(19) United States
(12) Patent Application Publication
(10) Pub. No.: US 2012/0107613 A1
(43) Pub. Date: May 3, 2012

(54) Corrosion-resistant article coated with aluminum nitride

(75) Inventors: Shoji Kano, Annaka-shi (JP); Mitsumasa Kubota, Nirasaki-shi (JP); Mitsuo Tanaka, Nirasaki-shi (JP); Koji Kato, Annaka-shi (JP); Waichi Yamamura, Annaka-shi (JP)

(73) Assignee: SHIN-ETSU CHEMICAL CO., LTD., Tokyo (JP)

(21) Appl. No.: 13/137,837

(22) Filed: Sep. 16, 2011

(30) Foreign Application Priority Data
Oct. 29, 2010 (JP) 2010-243158

(51) Int. Cl. B32B 33/00; C23C 16/56; C23C 16/34; C23C 16/44; B32B 9/00; B32B 15/04

(52) U.S. Cl. 428/408; 428/698; 428/446; 428/469; 427/248.1

(57) ABSTRACT

A corrosion-resistant article is proposed which is coated with an aluminum nitride wherein the aluminum nitride grains contain oxygen by 0.1 mass % or greater but not greater than 20 mass % so that the thermal expansion coefficient of the coating layer is made even with that of the base body; the relative density of the coating layer is preferably 50% or higher but lower than 98%. It is preferred that the coating layer is first made by chemical vapor deposition and then subjected to an oxidizing atmosphere of a temperature of 700 degrees centigrade or higher but 1150 degrees centigrade or lower; or it is preferable that after the chemical vapor deposition step the coating layer is exposed to the natural atmosphere to adsorb hydrate and then subjected to a heat treatment in an inert atmosphere of a temperature of 900 degrees centigrade but 1300 degrees centigrade or lower.

### PRIORITY CLAIMED

The present non-provisional application claims priority, as per Paris Convention, from Japanese Application No. 2010-243158 filed on Oct. 29, 2010, the disclosure of which is hereby incorporated by reference herein in its entirety.

### TECHNICAL FIELD

The present inventions relate to an improvement in corrosion resistance of various articles such as electrostatic chuck used popularly in process lines for manufacturing heat dissipation substrate and semiconductor device, ceramic heater for heating wafer, and parts used in semiconductor manufacturing apparatus such as disk plate, shower plate and ring-shaped device (hereinafter, these articles are referred to as “article”).

### BACKGROUND OF THE INVENTION

In semiconductor manufacturing process, an oxide film and a metal film to make circuit pattern are deposited on silicon wafers by chemical vapor deposition (CVD) performed in a CVD apparatus, and films are grown over silicon wafers as a result of thermal etching and plasma etching conduced in an etching apparatus, and in order to remove such films that have grown on articles other than the silicon wafers, periodical self cleaning is conducted using highly corrosive fluorine-containing gases such as NF₃, CF₄, and ClF₃.

Those articles that constitute the semiconductor apparatus such as susceptor, clamp ring, and focus ring over which the wafer is sited need be resistant to such highly corrosive gasses and are conventionally made of silicon (Si), quartz glass, silicon carbide, and the like, the choice being made depending on the application.

However, these conventionally used materials were not without a problem of one sort or another. For example, in the case of quartz glass, it undergoes reactions in the presence of a highly reactive fluorine-containing gas and yields a reaction product, like silicon fluoride, which has a high vapor pressure and thus sublimates to cause continuous erosion to proceed in the quartz glass articles, which eventually may disappear.

Also, in the case of silicon carbide, which is basically superior to quartz glass in corrosion resistance, the kind of silicon carbide used in a semiconductor manufacturing apparatus is silicon-admixed silicon carbide so that the admixed silicon part reacts with the fluorine-containing gas and dissipates whereby the silicon carbide becomes loose and easy to separate from the article of originally closely packed structure, causing generation of particles.

Further, in the case in which the article is made of sintered aluminum nitride, an infinitesimal amount of sintering additive is contained and the article would have a kind of grain boundary unique to the sintering method. For this reason, it has been known, when the article is exposed to the fluorine-containing gas for a long time, the portions of the sintering additive and the grain boundary are selectively etched, whereby the article is degraded with time, although in a lesser degree than in the cases of quartz glass and silicon carbide. So, in a long run, an article made of such a material is apt to generate particles. There have been studies made to improve the corrosion resistance of the surface of an article made of sintered aluminum nitride by oxidizing the surface, but still the selective etching of the grain boundaries, etc. remains as a problem.

On the other hand, aluminum-related materials such as aluminum (metallic), aluminum oxide (alumina) and aluminum nitride produce aluminum fluoride (AlF₃) after reacting with the fluorine-containing gas, and since the vapor pressure of this product is far lower compared to the products created from the above-mentioned quartz glass and silicon carbide, studies have been made to try this material.

For example, a proposal has been made to coat a heat resistant base body made of a sintered aluminum nitride containing carbon in an amount of 0.01 weight % or greater with a layer made of crystalline aluminum nitride having a thickness of 10 micrometers or greater (Publication-in-IP 1). Further, there is also a proposal which suggests, mainly characterized in manufacturing method, to deposit an aluminum nitride layer over the sintered body of aluminum nitride (Publication-in-IP 2).

However, there is a difference in thermal expansion coefficient between the ceramic base body made of sintered aluminum nitride and the coating layer made of aluminum nitride, and therefore in the case where this coating layer is created by CVD (chemical vapor deposition) method, this difference in thermal expansion coefficient causes the base body to warp during the cooling stage after the layer deposition, and also residual thermal stress is created both in the base body and the coating layer whereby a further warping is caused to impair the dimensional precision of the body and what is worse a crack may occur in the base body or the coating layer, or in the worst case the coating layer may exfoliate.

In the case where a crack occurs in the base body or the coating layer, there is a problematic possibility that that cracked portion becomes easier to erode and more apt to generate particles.

### PRIOR ART PUBLICATIONS

### Publications-in-IP

### [Publication-in-IP 1]

Japanese Patent Application Publication H06-163428

### [Publication-in-IP 2]

Japanese Patent Application Publication H02-59474

### BRIEF DESCRIPTION OF THE INVENTION

### The Problems the Invention Seeks to Solve

It is therefore an object of the invention to provide a corrosion-resistant article which comprises a heat resistant base body clad with an aluminum nitride (AlN) film (hereinafter also called “coating layer”) which does not warp when the coating layer is laid on the surface of the base body so that the dimensional precision is sustained.

### Means to Solve the Problems

The corrosion-resistant article according to the present invention is characterized in that a coating layer with which the base body is clad entirely or partially by means of CVD method contains oxygen in an amount of 0.1 mass % or greater but no more than 20 mass %.

It is preferable, respectively, that the amount of oxygen contained in the coating layer is 0.5 mass % or greater but no more than 15 mass %, that the relative density of the coating layer consisting chiefly of aluminum nitride is controlled to be 50% or greater but not 98% or greater, that the coating layer is heat-treated in an oxygen-containing atmosphere at a temperature of 700 degrees centigrade or higher but no higher than 1150 degrees centigrade after being grown by CVD method, or that the coating layer is exposed to the natural atmosphere to thereby let a hydrate form on it and then heat-treated in an inert atmosphere.

Furthermore, it is preferable that the chief material to make the base body of the corrosion-resistant article is pyrolytic boron nitride (PBN), a sintered compact of a mixture of boron nitride and aluminum nitride, PBN-coated graphite, aluminum nitride, an oxide of rare earth metal, aluminum oxide, silicon oxide, zirconia (zirconium dioxide), SiAlON (Si₃N₄.Al₂O₃), graphite, silicon, or a high-melting point metal.

The method for manufacturing the corrosion-resistant article according to the invention is characterized by comprising the steps of forming over a heat-resistant base body by a CVD method a coating layer which is chiefly made of aluminum nitride and has a relative density of 50% or greater but not 98% or greater, and causing the coating layer to contain oxygen in an amount of 0.1 mass % or greater but no more than 20 mass %.

A preferred method for the step of causing the coating layer to contain oxygen in an amount of 0.1 mass % or greater but no more than 20 mass % is to apply a heat treatment in an oxygen-containing atmosphere at a temperature of 700 degrees centigrade or higher but no higher than 1150 degrees centigrade.

It is also a preferable method for attaining this same object to expose the coating layer to the natural atmosphere containing moisture to thereby let hydrate be adsorbed to the coating layer and then to apply a heat treatment in an inert atmosphere at a temperature of 900 degrees centigrade or higher but not 1300 degrees centigrade or higher.

### Effects of the Invention

According to the present invention, an article is constituted by a base body of heat-resistant material and a coating layer of aluminum oxide and/or aluminum oxynitride, which are made by introducing oxygen into the grains of AlN, so that it becomes possible to adjust the thermal expansion coefficient of the coating layer to that of the base body, and as a result the dimensional precision is preserved, and the occurrence of warping and crack in the base body is reduced. Furthermore, there is an added advantage of preventing the degradation of the coating layer (film) caused by the repeated creation of thermal stress as the article is heated and cooled in use.

### EMBODIMENTS OF THE INVENTION

The present invention shall be explained in detail through the description of its Examples and Comparative Examples.

The inventors put efforts to the study for improving the corrosion resistance of articles consisting of a heat-resistant base body covered wholly or in part with an aluminum nitride coating layer, which articles are used under severe conditions such as in the presence of highly corrosive gases, especially like fluorine-containing gases, and eventually they came to possess a new knowledge that it is possible to reduce the difference in thermal expansion coefficient between the base body and the coating layer through inclusion of oxygen into the coating layer whereby it is possible to avoid cracking and exfoliation of the coating layer, and hence the present invention was made.

In particular, the inventors found that at the time of the formation of the aluminum nitride (AlN) coating layer by CVD method to cover the heat-resistant base body entirely or in part, it is possible to adjust the thermal expansion coefficient of the coating layer to that of the base body through making the content of oxygen in the coating layer 0.1 mass % or higher but not higher than 20 mass %, and as a result it has become possible to preserve the dimensional precision and to reduce the warping and cracking of the base body and also it has become possible to prevent cracking of the coating layer even if its thickness is made sufficiently large, and thus even in a high-temperature process it is now possible to prevent creation of particles caused by cracking.

Thus, the present invention was contrived in view of attaining the above-mentioned problems, and is characterized in that the content of oxygen in the crystal grains of the aluminum nitride (AlN) coating layer is controlled to 0.1 mass % or higher but not higher than 20 mass %, to thereby cause the thermal expansion coefficient of the coating layer to be similar to that of the base body.

If the content of oxygen is smaller than 0.1 mass %, the thermal expansion coefficient of the coating layer does not alter substantially, but when the base body happens to have a thermal expansion coefficient similar to that of the coating layer, there would be scarce warping in the coating layer. Preferably the oxygen content is no less than 0.5 mass %; however, a problem of reduced corrosion resistance against fluorine-containing gas arises. Also, when the oxygen content becomes over 20 mass %, the coating layer turns a little more fragile and would crack more easily. Thus, it is preferred that the oxygen content does not exceed 15 mass %.

By covering a heat-resistant base body entirely or in part through CVD method with a coating layer consisting of aluminum nitride which is adapted to have a relative density of 50% or greater but not 98% or greater, it is possible to attain a uniform introduction of oxygen into the coating layer.

If the relative density is lower than 50%, the coating layer becomes too fragile. When it is 98% or greater, it becomes difficult to distribute oxygen uniformly, but more oxygen collects toward the surface and thus the coating layer becomes more apt to crack and exfoliate. A preferred range for the relative density is 60% or higher but 95% or lower. With the density within this range, it is possible to increase the coating layer thickness sufficiently without experiencing cracking and thus it is possible to suppress the occurrence of particles caused by cracking even when in a high temperature process.

The relative density can be controlled by altering the reaction conditions, especially the reaction temperature.

Incidentally, what is meant herein by relative density is the ratio of the bulk density of the coating film formed by CVD method, etc. to the theoretical density of aluminum nitride, and it can be obtained easily from the film thickness and the weight measured by means of micrometer and electronic balance.

The above-described coating layer or film may be heat-treated in an oxygen-containing atmosphere at a temperature of 700 degrees centigrade or higher but 1150 degrees centigrade or lower after being formed by CVD method. By utilizing the CVD method, it is possible to obtain a high purity aluminum nitride coating layer, and in turn it is possible to obtain high purity aluminum oxide and/or aluminum oxynitride when it is later heat-treated in the oxidizing atmosphere.

Conventional articles like shower plate and ring used in a semiconductor manufacturing apparatus, such as ones made of sintered ceramics, are apt to be a source for metallic contamination as they dissipate metallic impurities, and are also apt to crack causing problems, but the articles according to the present invention, which are clad with high purity coating layer, are free from cracking and are highly corrosion resistant to guarantee a long life, and do not cause metallic contamination.

If the heat-treatment is conducted at temperatures lower than 700 degrees centigrade, the coating layer fail to pick up sufficient oxygen, and it retains the deformation it obtained it acquired as of the time of film coating. Therefore, it is preferred that the heat treatment temperature is 750 degrees centigrade or higher.

If the heat treatment temperature is higher than 1150 degrees centigrade or higher, the resultant film tends to be fragile and easy to crack. Thus, it is preferably 1100 degrees centigrade or lower.

The coating layer can contain oxygen in it by being first exposed to the natural atmosphere to thereby have a hydrate form on it, and then by being heat-treated in an inert atmosphere at a temperature of 900 degrees centigrade or higher but not higher than 1300 degrees centigrade. As the coating plate is exposed to the natural atmosphere, moisture is adsorbed to it. Then, as it is heat-treated at a temperature of 900 degrees centigrade or higher but not higher than 1300 degrees centigrade, oxide film is thought to form on the surfaces of the AlN crystalline grains whereby the thermal expansion coefficient of the coating layer is altered.

Preferably, the coated article is let to sit for a day or so in a constant-temperature, constant-humidity chamber set at a temperature of 30 degrees centigrade and at a humidity of 50% or higher.

The chief material to make the heat-resistant base body of the article may be PBN, a sintered compact of a mixture of boron nitride and aluminum nitride, PBN-coated graphite, aluminum nitride, an oxide of a rare earth metal, aluminum oxide, silicon oxide, zirconia, SiAlON, graphite, silicon or a high-melting point metal. The base body made of any of these can withstand effectively a high temperature film formation process at temperatures as high as 800 degrees centigrade in the semiconductor film formation apparatuses.

The coating layer is formed by a chemical vapor deposition method wherein an organic metallic compound containing aluminum or aluminum chloride and ammonium are used as the raw materials, and when the reaction temperature is set to a value from 800 degrees centigrade to 1200 degrees centigrade, it is possible to obtain a high-purity coating film having an excellent crystallinity. With the use of chemical vapor deposition method, it is possible to suppress the metallic impurities to so low as 50 ppm or less so that the resultant articles are suitable to use as parts for semiconductor manufacturing apparatus, heater and electrostatic chuck, and the like wherein high purity is a must.

If the surface of a sintered body is simply subjected to oxidizing treatment, the metallic impurities (sintering additive, Ca, Na, heavy metals, etc.) which exist in the surface of the sintered body where oxidation takes place, as well as inside the sintered body, are feared to cause metallic contamination.

By making the thickness of the coated film to be 1 micrometer or greater but not greater than 500 micrometers, the resulting corrosion resistance is sufficient for use in most of the use conditions.

With a thickness smaller than one micrometer, a problem may arise wherein a partial defect happens to exist and there the underneath base body is exposed and eroded to generate particles. It is more preferred that the thickness is 10 micrometers or greater. When the thickness is greater than 500 micrometers, there is a chance that the coating film exfoliates from the base body at the interface owing to the increased internal stress of the film, and besides it takes a long time to make such a film and the manufacturing cost would unjustifiably high. It is more preferable that the thickness is 300 micrometers or smaller.

### EXAMPLES

The present invention shall be explained in a more detailed manner by way of Examples and Comparative Examples, but the invention scope shall not be limited by these descriptions.

### Group 1 Examples and Group 1 Comparative Examples

A coating layer was laid by thermal CVD method all over the surface of a base body made of a sintered compact of aluminum nitride measuring 50 mm in length by 15 mm in width by 0.5 mm in thickness.

In this film laying process, trimethyl aluminum was used as one of the raw materials, i.e., the organic metallic compound including aluminum; and this material was supplied by a bubbler method, and argon gas was used for the bubbling. Incidentally, it has been confirmed that a similar result is obtained when nitrogen, hydrogen, helium or the like is used as the bubbling gas.

Trimethyl aluminum was placed in a constant-temperature chamber where it was preserved at a temperature of 25 degrees centigrade; the flow rate of the argon for bubbling was set to 2 liter/min; the pressure inside the cylinder was controlled such that the gauge pressure became 10 kPa. The feed rate of trimethyl aluminum on this occasion was 0.3 mol/hr.

On the other hand, ammonium was supplied in a manner such that the liquid ammonium was directly evaporated by heating and its feed rate was controlled by MFC (mass flow controller) to a feed rate of 1.7 mol/hr.

While the pressure in the reaction furnace was maintained at as low as 50 Pa or so in terms of absolute pressure as the gas was kept being pulled out by a vacuum pump, a coating layer of a thickness of 50 micrometers and a relative density of 80% was formed.

The base body formed with the coating layer was heat-treated in an oxygen stream at various temperatures ranging from 650 degrees centigrade to 1200 degrees centigrade. A base body without being heat-treated was also prepared for evaluation as a comparative example piece. The result of the evaluation as detailed below is shown in Table 1.

Warping and oxygen content were measured with respect to each of coated articles which were made under respectively different conditions. The amount of warping was measured by a laser displacement sensor, and if a certain one of two coated main faces was concaved the warping amount was represented by a minus number, and if the other main face was concaved the warping amount was represented by a plus number.

The oxygen content in the film was quantitatively analyzed by GDMS (glow discharge mass spectrometry) in terms of a ratio in relation to AlN.

The corrosion resistance against fluorine plasma was evaluated in the following manner: a coated base material was positioned in a plasma etching treatment apparatus RIE-10NR (a product of SAMCO Inc.), wherein CF₄ gas and oxygen were let to stream at a rate of 50 sccm (standard cubic centimeter per minute) each and the pressure was maintained at 10 Pa, and plasma was generated while the RF power was adjusted at 500 W and an etching test was conducted for 10 hours continuously. When the consumption amount was greater than that in the case of sintered aluminum nitride, the sample was estimated as NG, no good, and if smaller the estimation was good.

TABLE 1

| | | | | Oxygen | | Overall |
|---|---|---|---|---|---|---|
| | | | Warping of | content | | Evaluation |
| | | Oxidizing | Sample after | after | | considering |
| | | Treatment | Oxidizing | Oxidizing | | warping and |
| | Sample | Temperature | Treatment | Treatment | corrosion | corrosion |
| | No. | (° C.) | (μm) | (%) | resistance | resistance |
| Comparative | 1 | no oxidizing | −160 | 0.05 | NG | NG |
| | 2 | 650 | −130 | 0.08 | NG | NG |
| Inventive | 3 | 700 | −60 | 0.1 | good | good |
| | 4 | 850 | 10 | 0.55 | good | good |
| | 5 | 900 | 20 | 2.5 | good | good |
| | 6 | 950 | 40 | 4.2 | good | good |
| | 7 | 1000 | 55 | 7.5 | good | good |
| | 8 | 1050 | 70 | 12.5 | good | good |
| | 9 | 1100 | 85 | 15.5 | good | good |
| | 10 | 1150 | 120 | 20.0 | good | relatively good |
| Comparative | 11 | 1200 | 300 | 20.5 | — | NG, because |
| | | | | | | film cracked |
| | | | | | | during |
| | | | | | | oxidization |

As is shown in Table 1, a sample of which the film did not receive the heat-treatment in the oxidizing atmosphere warped badly and the dimensional precision was poor. When a sample received the heat-treatment and the oxidizing treatment temperature was 650 degrees centigrade, the sample warped substantially and the corrosion resistance against fluorine plasma was not improved. The samples that were heat-treated at 700-1150 degrees centigrade showed only slight warping and the dimensional precision could be confirmed excellent. When the temperature for the heat-treatment was 1200 degrees centigrade, the sample plate warped extremely and the film was cracked.

Now, in this group of examples, the samples adopted a base body made of a sintered compact of aluminum nitride, but it was confirmed that when the base body was made of alumina it was possible to suppress the warping by the same means as in the case of this group test (see Table 2).

TABLE 2

| | | | | Oxygen | | Overall |
|---|---|---|---|---|---|---|
| | | | Warping of | content | | Evaluation |
| | | Oxidizing | Sample after | after | | considering |
| | | Treatment | Oxidizing | Oxidizing | | warping and |
| | Sample | Temperature | Treatment | Treatment | corrosion | corrosion |
| | No. | (° C.) | (μm) | (%) | resistance | resistance |
| Comparative | 12 | no oxidizing | −200 | 0.05 | NG | NG |
| | 13 | 650 | −150 | 0.08 | NG | NG |
| Inventive | 14 | 700 | −70 | 0.1 | good | good |
| | 15 | 850 | 20 | 0.55 | good | good |
| | 16 | 900 | 35 | 2.5 | good | good |
| | 17 | 950 | 55 | 4.2 | good | good |
| | 18 | 1000 | 65 | 7.5 | good | good |
| | 19 | 1050 | 80 | 12.5 | good | good |
| | 20 | 1100 | 95 | 15.5 | good | good |
| | 21 | 1150 | 120 | 20.0 | good | relatively |
| | | | | | | good |
| Comparative | 22 | 1200 | 300 | 20.5 | — | NG, because |
| | | | | | | film cracked |
| | | | | | | during |
| | | | | | | oxidization |

As is shown in Table 2, a sample of which the film did not receive the heat-treatment in the oxidizing atmosphere warped much and the dimensional precision was poor. When a sample received the heat-treatment and the oxidizing treatment temperature was 650 degrees centigrade, the sample warped substantially and the corrosion resistance against fluorine plasma was not improved. The samples that were heat-treated at 700-1150 degrees centigrade showed only slight warping and the dimensional precision could be confirmed excellent. When the temperature for the heat-treatment was 1200 degrees centigrade, the sample plate warped extremely and the film was cracked.

### Group 2 Examples and Group 2 Comparative Examples

Samples consisting of a base body formed with a coating layer which was laid in the same manner as in Group 1 Examples and Group 1 Comparative Examples, were directly exposed to the natural atmosphere in a constant-temperature, constant-humidity chamber, which was set at a temperature of 30 degrees centigrade and at a humidity of 60%, for 10 hours; thereafter, the samples were subjected to a heat-treatment in an inert atmosphere consisting of Ar gas, and as the result the warping amount could be similarly suppressed. The results are shown in Table 3.

TABLE 3

| | | | | | | Overall |
|---|---|---|---|---|---|---|
| | | Inert | Warping of | Oxygen content | | Evaluation |
| | | Atmosphere | Sample after | after Inert | | considering |
| | | Heat-Treatment | Inert Atmosphere | Atmosphere | | warping and |
| | Sample | Temperature | Heat-Treatment | Heat-Treatment | corrosion | corrosion |
| | No. | (° C.) | (μm) | (%) | resistance | resistance |
| Comparative | 1-a | no treatment | −160 | 0.05 | NG | NG |
| | 2-a | 850 | −40 | 0.07 | NG | NG |
| Inventive | 3-a | 900 | −20 | 0.1 | good | good |
| | 4-a | 950 | 3 | 0.57 | good | good |
| | 5-a | 1000 | 8 | 2.4 | good | good |
| | 6-a | 1050 | 15 | 4.3 | good | good |
| | 7-a | 1150 | 22 | 7.4 | good | good |
| | 8-a | 1200 | 35 | 12.7 | good | good |
| | 9-a | 1250 | 42 | 15.8 | good | good |
| | 10-a | 1300 | 55 | 20.0 | good | relatively |
| | | | | | | good |
| Comparative | 11-a | 1350 | 300 | 20.7 | — | NG, because |
| | | | | | | film cracked |
| | | | | | | during |
| | | | | | | oxidization |

As is shown in Table 3, the sample of which the film did not receive the heat-treatment after being exposed to the natural atmosphere in a constant-temperature, constant-humidity chamber set at a temperature of 30 degrees centigrade and at a humidity of 60% for 10 hours, warped much and the dimensional precision was poor. When a sample received the heat-treatment and the heat-treatment temperature was 850 degrees centigrade, the sample warped only slightly but the corrosion resistance against fluorine plasma was not improved. The samples that were treated at 900-1300 degrees centigrade showed only slight warping and the dimensional precision and the corrosion resistance could be confirmed excellent. When the temperature for the heat-treatment was 1350 degrees centigrade, the sample plate warped extremely and the film was cracked.

Now, in this group of examples, the samples adopted a base body made of a sintered compact of aluminum nitride, but it was confirmed that when the base body was made of alumina it was possible to suppress the warping by the same means as in the case of this group test. The result is entered in Table 4.

TABLE 4

| | | | | | | Overall |
|---|---|---|---|---|---|---|
| | | Inert | Warping of | Oxygen content | | Evaluation |
| | | Atmosphere | Sample after | after Inert | | considering |
| | | Heat-Treatment | Inert Atmosphere | Atmosphere | | warping and |
| | Sample | Temperature | Heat-Treatment | Heat-Treatment | corrosion | corrosion |
| | No. | (° C.) | (μm) | (%) | resistance | resistance |
| Comparative | 12-a | no treatment | −200 | 0.05 | NG | NG |
| | 13-a | 850 | −65 | 0.07 | NG | NG |
| Inventive | 14-a | 900 | −50 | 0.1 | good | good |
| | 15-a | 950 | −35 | 0.56 | good | good |
| | 16-a | 1000 | −20 | 2.6 | good | good |
| | 17-a | 1050 | 10 | 4.1 | good | good |
| | 18-a | 1150 | 38 | 7.7 | good | good |
| | 19-a | 1200 | 52 | 12.4 | good | good |
| | 20-a | 1250 | 78 | 15.7 | good | good |
| | 21-a | 1300 | 98 | 20.0 | good | good |
| Comparative | 22-a | 1350 | 300 | 20.4 | — | NG, because |
| | | | | | | film cracked |
| | | | | | | during |
| | | | | | | oxidization |

As is shown in Table 4, a sample of which the film did not receive the heat-treatment after being exposed to the natural atmosphere in a constant-temperature, constant-humidity chamber set at a temperature of 30 degrees centigrade and at a humidity of 60% for 10 hours, warped much and the dimensional precision was poor. When a sample received the heat-treatment and the heat-treatment temperature was 850 degrees centigrade, the sample warped only slightly but the corrosion resistance against fluorine plasma was not improved. The samples that were treated at 900-1300 degrees centigrade showed only slight warping and the dimensional precision and the corrosion resistance could be confirmed excellent. When the temperature for the heat-treatment was 1350 degrees centigrade, the sample plate warped extremely and the film was cracked.

### Group 3 Examples and Group 3 Comparative Examples

By the same method as in the Group 1 Examples, a coating layer was deposited all over the surface of a base body made of a sintered compact of aluminum nitride measuring 50 mm in length by 15 mm in width by 0.5 mm in thickness, at various temperatures, and the resultant layer had a relative density varying from 47.5% to 98.0% and a thickness of 50 micrometers. The base body thus coated with a film was subjected to a heat treatment in an oxidizing atmosphere at 800 degrees centigrade. The result is shown in Table 5.

TABLE 5

| | | Relative | | Warping of | Oxygen | | Overall |
|---|---|---|---|---|---|---|---|
| | | Density | | Sample | content | | Evaluation |
| | | of | Temperature | after | after | | considering |
| | | Coating | for Oxidizing | Oxidizing | Oxidizing | | warping and |
| | Sample | Layer | Atmosphere | Treatment | Treatment | corrosion | corrosion |
| | No. | (%) | (° C.) | (μm) | (%) | resistance | resistance |
| Comparative | 23 | 47.5 | 800 | 120 | 22 | NG | NG |
| Inventive | 24 | 50.0 | 800 | 100 | 19 | good | relatively |
| | | | | | | | good |
| | 25 | 54.7 | 800 | 80 | 13 | good | good |
| | 26 | 60.5 | 800 | 30 | 5 | good | good |
| | 27 | 80.0 | 800 | −10 | 0.4 | good | good |
| | 28 | 86.8 | 800 | −50 | 0.3 | good | good |
| | 29 | 95.4 | 800 | −80 | 0.2 | good | good |
| | 30 | 97.8 | 800 | −100 | 0.12 | good | relatively |
| | | | | | | | good |
| Comparative | 31 | 98.0 | 800 | −170 | 0.08 | — | NG, because |
| | | | | | | | film cracked |
| | | | | | | | during |
| | | | | | | | oxidization |

As is shown in Table 5, when the relative density was 47.5%, the fluorine plasma resistance was poor, and when it was 98.0% the film was exfoliated. When 50.0% to 97.8%, the warping was suppressed, and the fluorine plasma resistance was good and the coating layer did not crack.

Now, in this group of examples, the oxidizing treatment was conducted at a temperature of 800 degrees centigrade, but similar results were obtained in the case of temperatures of 700 to 1150 degrees centigrade.

### Group 4 Examples and Group 4 Comparative Examples

By the same method as in the Group 1 Examples, a coating layer was deposited all over the surface of a base body made of a sintered compact of aluminum nitride measuring 50 mm in length by 15 mm in width by 0.5 mm in thickness, at various temperatures, and the resultant layer had a relative density varying from 47.5% to 98.0% and a thickness of 50 micrometers. The base body thus coated with a film was directly exposed to the natural atmosphere in the constant-temperature, constant-humidity chamber, which was set at a temperature of 30 degrees centigrade and at a humidity of 60%, for 10 hours; thereafter, the samples were subjected to a heat-treatment in an inert atmosphere consisting of Ar gas. The results are shown in Table 6.

TABLE 6

| | | Relative | | Warping of | Oxygen | | Overall |
|---|---|---|---|---|---|---|---|
| | | Density | | Sample | content | | Evaluation |
| | | of | Temperature | after | after | | considering |
| | | Coating | for Oxidizing | Oxidizing | Oxidizing | | warping and |
| | Sample | Layer | Atmosphere | Treatment | Treatment | corrosion | corrosion |
| | No. | (%) | (° C.) | (μm) | (%) | resistance | resistance |
| Comparative | 23-a | 47.5 | 1100 | 50 | 27 | NG | NG |
| Inventive | 24-b | 50.0 | 1100 | 10 | 20 | good | relatively |
| | | | | | | | good |
| | 25-c | 54.7 | 1100 | 0 | 15 | good | good |
| | 26-d | 60.5 | 1100 | −20 | 13 | good | good |
| | 27-e | 80.0 | 1100 | −45 | 3 | good | good |
| | 28-f | 86.8 | 1100 | −50 | 2 | good | good |
| | 29-g | 95.4 | 1100 | −90 | 0.5 | good | good |
| | 30-h | 97.8 | 1100 | −120 | 0.11 | good | relatively |
| | | | | | | | good |
| Comparative | 31-i | 98.0 | 1100 | −200 | 0.07 | — | NG, because |
| | | | | | | | film cracked |
| | | | | | | | during |
| | | | | | | | oxidization |

As is shown in Table 6, when the relative density was 47.5%, the fluorine plasma resistance was poor, and when it was 98.0% the film was exfoliated. When 50.0% to 97.8%, the warping was suppressed, and the fluorine plasma resistance was good and the coating layer did not crack.

In this group of examples, the oxidizing treatment was conducted at a temperature of 1100 degrees centigrade, but similar results were obtained in the case of temperatures of 900 to 1300 degrees centigrade.

1. A corrosion-resistant article coated with aluminum nitride consisting of a base body and a coating layer with which said base body is coated at least partly, characterized in that the coating layer is made chiefly of aluminum nitride and is formed by chemical vapor deposition and contains oxygen in an amount of 0.1 mass % or greater but not greater than 20 mass %.

2. A corrosion-resistant article as claimed in claim 1 wherein said chiefly aluminum nitride coating layer contains oxygen in an amount of 0.5 mass % or greater but not greater than 15 mass %.

3. A corrosion-resistant article as claimed in claim 1 wherein said chiefly aluminum nitride coating layer has a relative density of 50% or greater but not greater than 98%.

4. A corrosion-resistant article as claimed in claim 1, wherein said coating layer is formed by chemical vapor deposition and subsequent heat-treatment in an oxidizing atmosphere at a temperature of 700 degrees centigrade or higher but not higher than 1150 degrees centigrade.

5. A corrosion-resistant article as claimed in claim 1, wherein said coating layer is formed by being exposed to natural atmosphere to thereby adsorb hydrate and then subjected to a heat-treatment in an inert atmosphere.

6. A corrosion-resistant article as claimed in claim 1 wherein said base body is made chiefly of any one of pyrolytic boron nitride, a sintered compact of a mixture of boron nitride and aluminum nitride, graphite coated with pyrolytic boron nitride, aluminum nitride, an oxide of rare earth metal, aluminum oxide, silicon oxide, zirconia, SiAlON, graphite, silicon, and a high-melting point metal.

7. A method for manufacturing a corrosion-resistant article consisting of a base body and a coating layer with which said base body is coated at least partly, characterized by comprising the steps of (i) coating at least a part of the base body with the layer made chiefly of aluminum nitride by chemical vapor deposition in a manner such that a relative density of the resultant coating layer becomes 50% or higher but lower than 98% and (ii) introducing oxygen into the coating layer in a manner such that an oxygen content of the coating layer becomes 0.1 mass % or greater but not greater than 20 mass %.

8. A method for manufacturing a corrosion-resistant article as claimed in claim 7, characterized by that said step (ii) comprises subjecting the coating layer to a heat-treatment in an oxidizing atmosphere at a temperature of 700 degrees centigrade or higher but not higher than 1150 degrees centigrade.

9. A method for manufacturing a corrosion-resistant article as claimed in claim 7, characterized by that said step (ii) comprises subjecting the coating layer to natural atmosphere to thereby adsorb hydrate and subjecting the coating layer to a heat-treatment in an inert atmosphere at a temperature of 900 degrees centigrade or higher but not higher than 1300 degrees centigrade.
